(19) United States
(12) Patent Application Publication
(10) Pub. No.: US 2026/0239792 A1
(43) Pub. Date: Aug. 13, 2026

(54) Growing Multiple microLEDs Horizontally and Separately

(71) Applicant: Binh Tinh Tran, GRAHAM, NC (US)

(72) Inventor: Binh Tinh Tran, GRAHAM, NC (US)

(21) Appl. No.: 19/048,913

(22) Filed: Feb. 8, 2025

(51) Int. Cl. H10H 29/01; H10H 20/01

(52) U.S. Cl. CPC H10H 29/011; H10H 20/0137; H10H 29/0364

(57) ABSTRACT

A method is provided for growing multiple inorganic light-emitting diodes (LEDs), including mini light-emitting diodes, micro light-emitting diodes, and ultraviolet light-emitting diodes (collectively referred to as microLEDs), on a single substrate. This method involves using a common substrate and contact layers to sequentially grow red, green, and blue microLEDs (RGB microLEDs) horizontally and separately with the aid of an oxide or nitride thin film mask. Both dry and wet etching techniques are employed to define the growth area and shape of each microLED. By growing multiple colors (R, G, B, and potentially more) of microLEDs on a single substrate, the need for transfer processes, such as micro-transfer printing, to pick up each R, G, and B microLED from the epi wafers and place them onto the backplane for forming an electronic display panel is eliminated. This technology reduces the need for millions of transfer steps to only one or a few steps and avoids disadvantages associated with other technologies.

### 3. TECHNICAL FIELD

This disclosure relates to R, G, and B microLED subpixels for electronic display development, specifically describing a method for growing all subpixels horizontally and separately on a single substrate.

### 4. BACKGROUND OF THE INVENTION

This invention pertains to a method for growing full display pixel RGB microLEDs on a single substrate, but separately and horizontally. An LED consists of a n-type and p-type semiconductor with an active layer, which may include single or multiple quantum wells and barriers, inserted between the two semiconductor types. When a forward bias is applied, free electrons from the n-type region gain enough energy to cross the junction and recombine with holes in the p-type region. Initially, free electrons in the n-type region are in the conduction band, but as they cross into the p-type region, they release energy and fall into holes in the valence band. This energy release during recombination in the active layer is in the form of light. For illumination devices, an LED must emit white light either on its own, through color conversion, or using a phosphor to convert its light to white light. In inorganic LEDs, the most common method for producing white light in electronic display panels is combining R, G, and B microLEDs.

In the last decade, mobile electronic devices have developed intensively, becoming essential for almost everyone due to their valuable functions in daily life. Today, electronic displays are used in many different devices, such as smartphones, smartwatches, equipment displays, tablets, augmented and virtual reality devices, and outdoor advertisement displays. These devices often share similar display architecture, components, and fabrication processes. One of the most challenging steps is picking up and placing subpixels from the epi wafer onto the backplane in an array of rows and columns. These subpixels may also need to be electrically connected to pixel controllers along the rows and columns for precise control. This process may be repeated up to millions of times, depending on the display panel and subpixel sizes, leading to numerous defective pixels. Consequently, extensive inspection and repair are required, which increases production costs.

To address this disadvantage, a prominent technique developed in recent years is the vertically stacked RGB microLEDs technology (U.S. Pat. No. 11,152,537 B2). This method involves growing GaN-based RGB microLEDs vertically on a substrate, allowing each subpixel to emit different colors based on the controller. According to the invention, the first subpixel is formed on a growth substrate, followed by the formation of a common anode layer on the first subpixel. A second subpixel is then formed on the common anode layer, with a current blocking layer added to prevent leakage current. Finally, a third subpixel is formed on the current-blocking layer. Each subpixel emits different light colors, and all subpixels are made using GaN semiconductor materials.

While this technique is promising because it uses the same material and can emit different light colors under varying electrodes and bias voltages, it has significant drawbacks. The main issue is the substantial interference between the active regions, which reduces the luminous efficiency and color quality of the device. Vertically stacked microLEDs also suffer from insufficient acceptors due to their multijunction nature. Additionally, carrier injection and recombination become uneven due to the distance between the multiple quantum wells and the p-electrode. This results in challenges in designing driving circuits, ultimately leading to low efficiency and poor color quality. Therefore, a better technique that avoids these significant issues is necessary to improve RGB microLEDs growth and solve the pixel transfer problem.

### 5. SUMMARY OF THE INVENTION

This technique involves growing microLED display pixels, including R, G, and B colors, directly on a single wafer in a horizontal and separate manner. This method significantly reduces the transfer process of subpixels from the epi wafer to the backplane from potentially millions of transfers to just one or a few. The substrate typically used for growing microLEDs is sapphire, but silicon (Si), gallium arsenide (GaAs), or gallium nitride (GaN), etc. can also be used.

The process typically begins with the growth of an undoped GaN layer on a sapphire substrate for the first type of microLED, followed by n-type GaN, an InGaN/GaN quantum well and barrier, and p-type GaN layers. The growth process is then paused, and the wafer is transferred to another system to deposit a mask layer, such as SiO₂, SiNₓ, or another suitable material. Lithography is used to define the growth regions for the second type of microLED, followed by etching, cleaning, and reloading the wafer into the system for subsequent microLED growth.

Metal-organic chemical vapor deposition (MOCVD) or molecular beam epitaxy (MBE) are common techniques used to grow RGB microLEDs. This growth technique creates complete RGB microLEDs directly on the substrate, reducing the transfer process to moving each epi wafer, with hundreds of thousands to millions of subpixels to the backplane, rather than transferring individual subpixels.

In some embodiments, as detailed below, the manufacturing process can create various scenarios, such as growing GaN-based R, G, and B microLEDs, or combining GaN-based G and B microLEDs with other materials, such as AlGaAs-based R microLEDs.

### 6. BRIEF DESCRIPTION OF THE DRAWINGS

FIG. 1 is a schematic view illustrating three types of microLEDs grown on a single substrate.

FIG. 2 is a view illustrating the process of growing the template and buffer layers for the microLEDs on the substrate.

FIG. 3 shows the substrate with two or more alignment marks created directly on it or on the buffer layer.

FIGS. 4 to 19 are views illustrating the process of growing three or more types of microLEDs on a single substrate, horizontally and separately.

### 7. DETAILED DESCRIPTION OF THE INVENTION

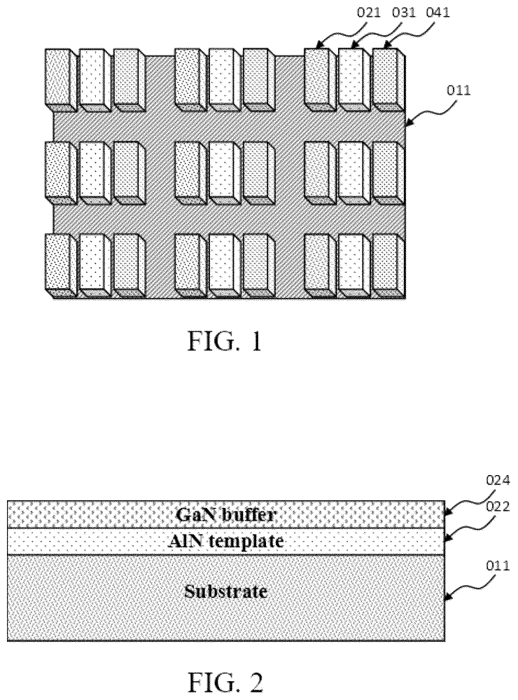

Hereinafter, some embodiments of this invention will be described in detail with reference to the related drawings. This present invention relates to a method for growing multiple types of microLEDs 021 031 041 on a single substrate 011, where each type emits a different color of light. For the purpose of transferring from the growth substrate 011 to the display backplane later, all microLEDs are not grown randomly but are instead grown in an array of columns and rows, as shown in FIG. 1. In some embodiments, subpixels and pixels are grown to have varying subpixel and pixel pitches, depending on the purpose of the final display application.

In the following, materials that can be used as a substrate for the growth of inorganic microLEDs typically include sapphire, silicon (Si), aluminum nitride (AlN), gallium nitride (GaN), gallium arsenide (GaAs), silicon carbide (SiC), and zinc oxide (ZnO), etc. Generally, a microLED structure comprises n-type and p-type semiconductor layers, as well as an active layer sandwiched between the n-and p-semiconductor layers. Group III-V semiconductor materials used for growing microLEDs include GaN, AlN, InN, GaAs, InP, and their alloys, such as AlₓGaₗ₋ₓN, Ga_{y}In_{1-y}N, AlₓGa_{y}In_{1-x-y}P, where 0≤x, y, and x+y≤1. Nitrogen-diluted silane (SiH₄) and bis(cyclopentadienyl)magnesium (Cp₂Mg) are commonly used as dopants to achieve n-type and p-type materials, respectively. However, other dopants such as Eu, Ge, Sn, Zn, Ca, and Sr can also be used individually or in combination. The active layer, which may consist of single or multiple quantum wells and barriers, is often formed from these semiconductor materials. Common contact layers are n-type and p-type semiconductor materials, such as n-GaN 042 and p-GaN 066, as shown in FIG. 6. An LED emits light only when voltage is applied in the forward direction of the diode.

Referring to FIG. 2 (note: all figures in this invention are not to scale), in some embodiments, R, G, and B microLEDs are sequentially grown together on a single substrate, horizontally separated from each other, using materials such as sapphire, Si, GaAs, or other suitable substrates. FIG. 2 illustrates a partial microLED structure with a substrate and two layers, which can be grown using an MOCVD or MBE system. An AlN template 022 is typically used before growing the GaN buffer layer 024, but the AlN layer can also be replaced by a low-temperature GaN layer. These two layers serve as the foundational layers for the subsequent growth of the full microLED structure. However, hexagonal boron nitride (h-BN) is also a good choice for replacing either AlN, GaN, or both, as it will facilitate the subsequent lift-off from the substrate before transferring onto the backplane for display fabrication. In this embodiment, the G microLED is grown first, followed by the B and R microLEDs, each grown sequentially. However, all microLEDs are grown horizontally and separately, so the order of growth may vary in some cases without issue.

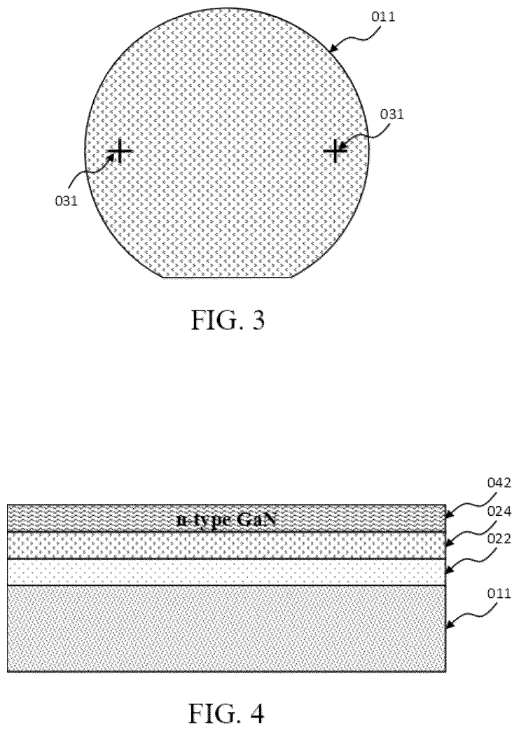

Before growing additional layers, two, three, or more alignment marks 031 must be created on the surface of the GaN buffer layer, as shown in FIG. 3. These alignment marks are crucial for the entire process, as will be explained later. Once the GaN buffer layer 024 is grown, a positive or negative photoresist, or a polymethyl methacrylate (PMMA) photoresist, is coated and patterned using techniques such as mask aligner, direct laser writing, automated stepper, or electron beam lithography. The substrate, now coated with photoresist, is then developed to expose the alignment marks 031 for subsequent etching in the designed area on the GaN buffer layer. This etching can be performed using dry etching techniques, such as reactive-ion etching, wet chemical etching, or a combination of both.

After etching, the photoresist layer is removed using solvents such as acetone, isopropanol, gamma butyrolactone, remover PG, or microposit remover 1165. Other methods like ultrasonic cleaning and plasma descumming can also be used to ensure complete removal of the photoresist. In some embodiments, the alignment marks 031 can be created directly on the substrate 011 (such as sapphire or Si) prior to growing any layer, rather than on the buffer layer 024.

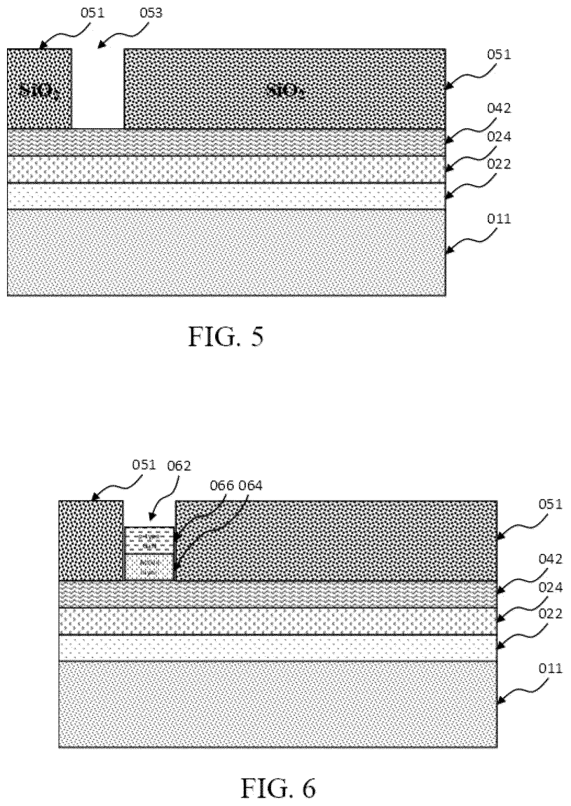

A GaN-based microLED, being a diode, typically includes n-type and p-type layers, along with an active layer, as mentioned above. The next layer in the structure is therefore usually n-type GaN 042 or heavily doped n+-type GaN, or a combination of both, depending on the specific design and the desired quantum efficiency, as illustrated in FIG. 4. To continue the growth of the first type of microLED structure, a mask layer, such as SiO₂, SiNₓ, or any suitable material 051, is deposited on top of the n-type layer 042 to a reasonable thickness, as shown in FIG. 5. This mask layer can be deposited using various techniques, including chemical vapor deposition, low-pressure chemical vapor deposition, plasma-enhanced chemical vapor deposition, atomic layer deposition, sputtering, or evaporation.

To define the area where the first type of microLED will grow, previously defined alignment marks, along with techniques such as mask aligner, direct laser writing, printed circuit board processing, or electron beam lithography can be utilized. A positive, negative, or PMMA photoresist is then applied. Afterward, the wafer is developed and etched to define the desired growth areas 053. A combination of dry and wet etching is essential at this stage to avoid damaging the underlying n-type GaN layer 042. Dry etching, such as reactive-ion etching, removes about 80% of the SiO₂ 051 (or other mask material), and wet etching, using hydrogen fluoride (HF) or buffered oxide etch (BOE), removes the remaining material.

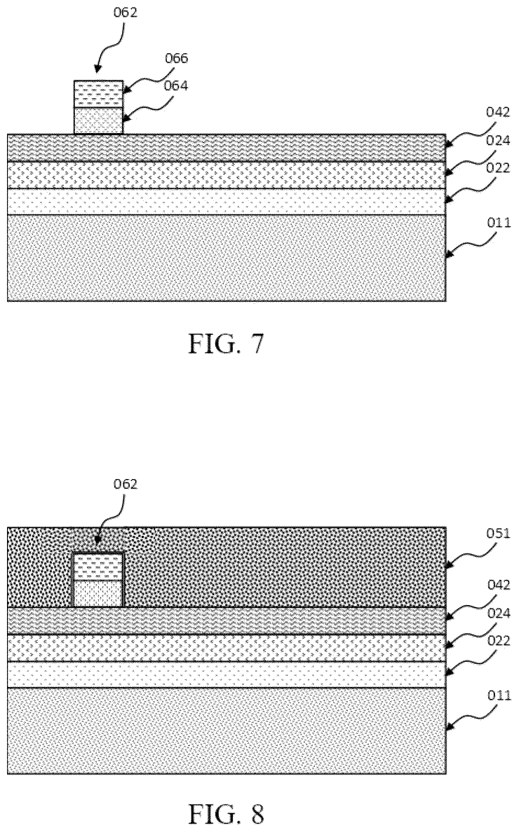

Once the areas are defined as shown in FIG. 5, the wafer is loaded into an MOCVD or MBE system to grow the remainder of the first type of microLED structure 062. This may include multiple quantum wells and barriers 064, p-type GaN 066, and a p+-GaN layer if required, as illustrated in FIG. 6. After growth is complete, the wafer is unloaded and dipped into HF or BOE to remove the SiO₂ or other mask materials used, as shown in FIG. 5. At this point, multiple first type of microLEDs 062 are successfully grown and stand alone on the substrate 011, as shown in FIG. 7.

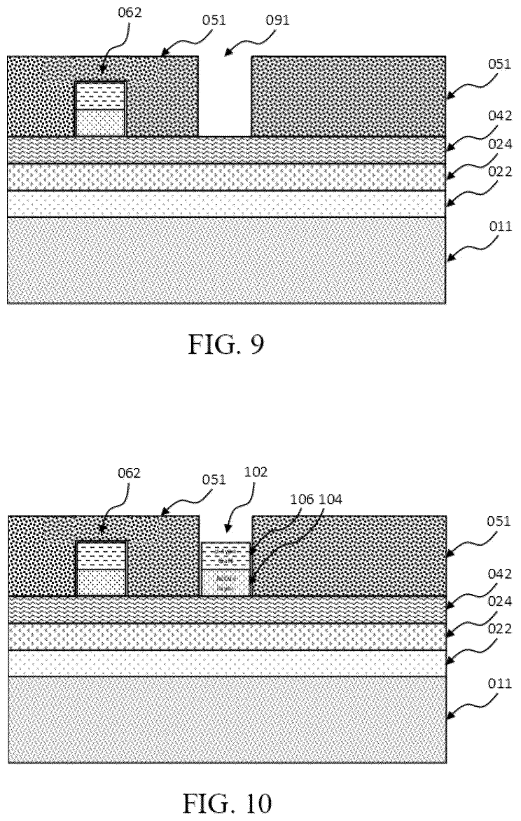

To grow multiple second type of microLEDs adjacent to the first type, a mask layer such as SiO₂ 051 or other suitable materials is again deposited across the entire wafer surface, as shown in FIG. 8. Following a process similar to that used for the first type of microLED, a positive, negative, or PMMA photoresist is applied. Using the previously defined alignment marks, techniques like mask aligner, direct laser writing, printed-circuit board processing, or electron beam lithography are used to align, expose, and develop the wafer, opening the designated areas 091 for the second type of microLED. A combination of dry and wet etching is then applied to open the SiO₂ 051 (or similar material), which serves as a mask for the second type of microLED growth, as shown in FIG. 9.

Next, the wafer is loaded into an MOCVD or MBE system to grow the remaining structure of the second type of microLED 102, following a process similar to that used for the first type of microLED 062, as illustrated in FIG. 10. This process also includes multiple quantum wells and barriers 104, p-type GaN 106, and a p+-GaN layer if required. However, in this embodiment, the thickness, doping concentration, and other conditions may differ from those of the first type of microLED, as it emits a different wavelength. After the growth is complete, the wafer is unloaded and immersed in HF or BOE to remove the SiO₂ or other mask materials applied in FIG. 8.

At this point, both the first 062 and second 102 types of microLEDs are grown and standing together on the substrate 011, as shown in FIG. 11. Since the first 062 and second 102 types of microLEDs emit different wavelengths of light, their structures may vary, particularly in terms of material composition, the thickness, number of layers, and other growth conditions.

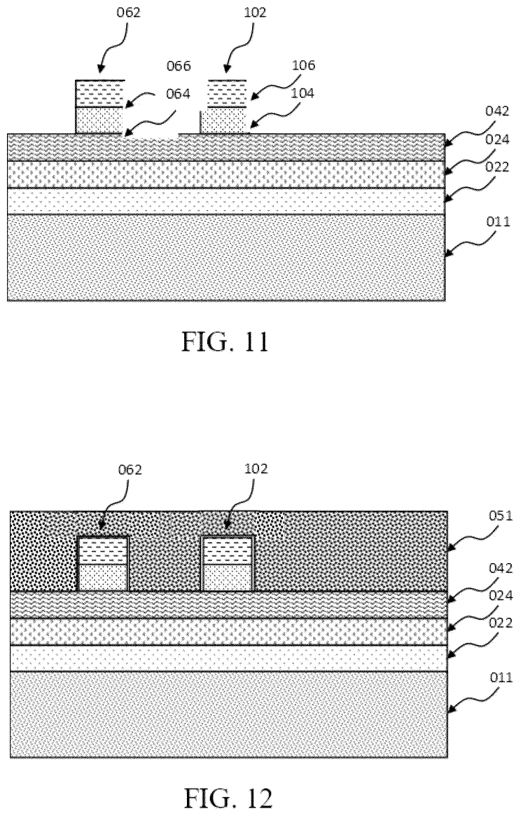

In some embodiments, the final type of microLED may vary. It could be a GaN-based R microLED, similar to the first 062 and second 102 types, or it may consist of other materials such as AlGaInP. In this particular embodiment, the process for fabricating a GaN-based R microLED follows the same steps as those used for the first 062 and second 102 types. This includes depositing a SiO₂ 051 (or another suitable material) mask layer over the entire wafer surface, as shown in FIG. 12. Photolithography and photoresist are then used to expose and define the target areas on the SiO₂ mask 131 aligning them with the previously defined alignment marks. The mask is then etched using a combination of dry and wet etches, as shown in FIG. 13.

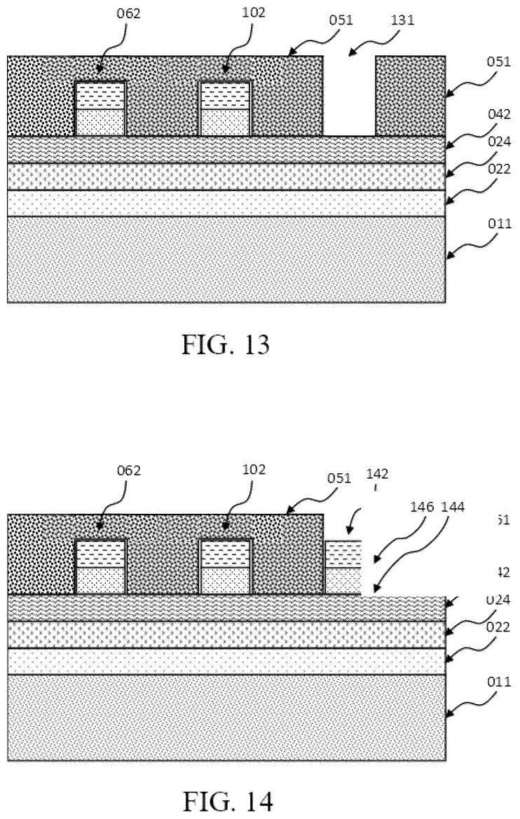

Following this, the wafer is loaded into an MOCVD or MBE system to grow the remaining structure of the third type of microLED 142, as illustrated in FIG. 14. Once the growth process is complete, the wafer is unloaded and immersed in HF or BOE to remove the SiO₂ or other mask materials 051, as depicted in FIG. 12.

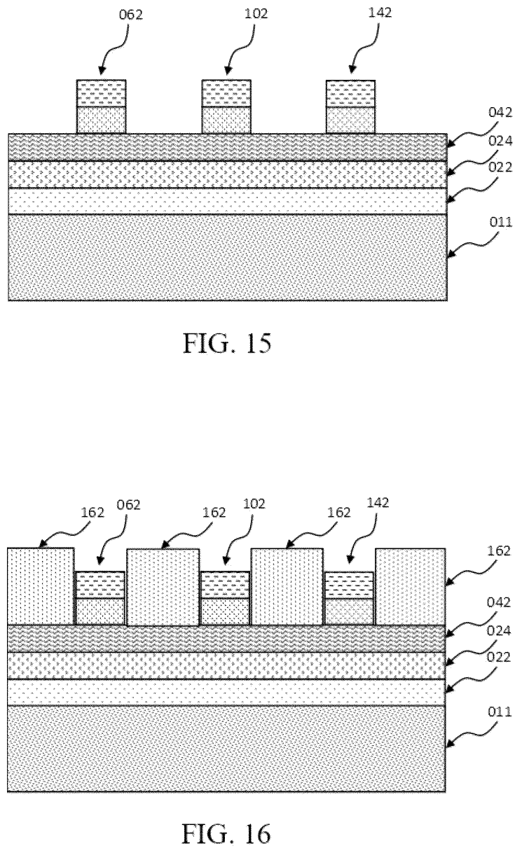

At this stage, the three types of microLEDs 062 102 142 are now fully grown and positioned on the substrate, as shown in FIG. 15. The third type of microLED 142, designed to emit R light, has a distinct structure. It typically includes an n-doped GaN layer 042 (already grown), followed by a low-indium-content InGaN/GaN layer, and then multiple quantum wells and barriers of high-indium-content InGaN/GaN 144. Finally, p-doped 146 and possibly p+-doped GaN layers are grown on top. The dopants used are SiH₄ for the n-type layers and Cp₂Mg for p-type layers. In some cases, a superlattice layer is also added between the n-GaN layer 042 and the low-indium-content InGaN/GaN layer to relieve strain in the active layer.

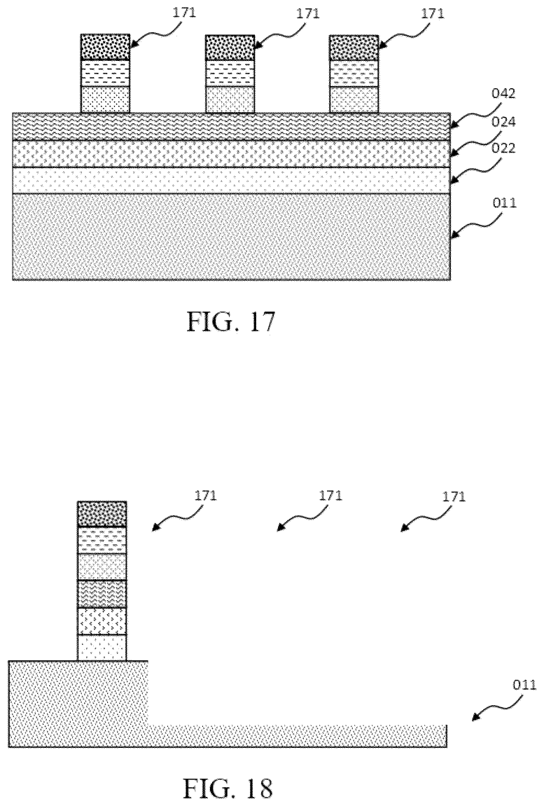

In this embodiment, once all three 062 102 142 or more types of microLEDs have been grown, the SiO₂ or other material mask is removed using HF or BOE, revealing the fully exposed microLED structures 062 102 142, as shown in FIG. 15. If necessary, reactive-ion etching can also be applied, but it must be performed carefully to avoid damaging the microLED structures when removing the SiO₂ or other material masks. In some embodiments, where two, three, or more types of microLEDs share a common n-type GaN layer 042, they must be separated before proceeding with further fabrication to ensure proper illumination and functionality. According to FIG. 16, a common positive, negative, or PMMA photoresist 162 is coated over the entire wafer surface and then exposed to reveal the top surface of all the microLEDs 062 102 142 using mask aligner, direct laser writing, printed-circuit board processing, automated stepper or electron beam lithography, aligned with the alignment marks on the substrate 031. Next, a metal layer 171, such as Ti, Ni, Cr, etc., is deposited by an electron beam evaporator or a sputter system, which acts as a mask, and then the photoresist is stripped away to lift-off the mask using acetone, isopropanol, gamma butyrolactone, remover PG, microposit remover 1165, or any suitable photoresist remover. Ultrasonic and plasma descum treatments may also be applied to completely remove the photoresist, as shown in FIG. 17.

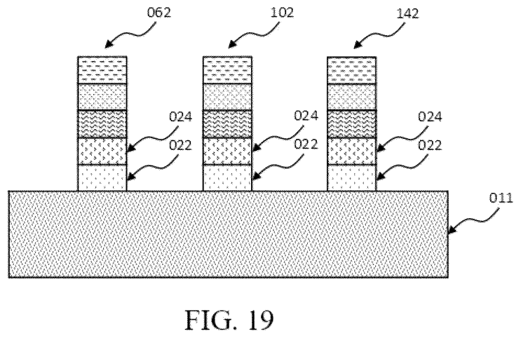

Reactive-ion etching is then employed to isolate each individual microLED from the n-type GaN layer 042 down to the substrate 011 or the GaN buffer 024, allowing for subsequent laser lift-off from the substrate 011, as illustrated in FIG. 18. This step is crucial to redefine the shape and size of all microLEDs, ensuring uniformity across the display. Since each growth cycle may leave microLEDs with non-uniform shapes, this process corrects such inconsistencies, contributing to a uniform display panel. Finally, the metal mask 171 on top of each microLED will be removed with HF, BOE, or metal etchants, revealing the fully exposed microLED structures 062 102 142 from the top down to the substrate, as shown in FIG. 19.

In a certain embodiment, the third type of microLED is based on AlGaInP and emits R light. The growth structure differs significantly and presents additional challenges. Since AlGaInP-based R LED cannot be grown directly on the existing n-GaN layer 042, an alternative approach is required. Either the n-GaN 042, GaN buffer 024, and the template 022 layers must be completely removed, with a mask layer such as SiO₂ or SiNₓ or a similar material 051 deposited to protect the first and second types of microLEDs before the third type (AlGaInP-based R LED) can be grown, or the full structure of the third type of microLED must be grown on the substrate 011 first, followed by the growth of the B or G microLEDs 062 102 as presented above.

In one special embodiment, the first and second types of microLEDs are covered with a SiO₂ or SiNₓ mask 051, which is then etched using a combination of dry and wet etching techniques to open the designated area 131 for growing the third type of microLED, as illustrated similarly in FIG. 13, starting from the substrate 011. Reactive-ion etching and wet etching are subsequently applied to etch down to the substrate 011 in the designated area, similar to 131, to prepare for the growth of R microLED only. Once the area is prepared, the third type of AlGaInP-based R microLED can be grown on the substrate, as shown similarly in FIG. 18, with the first and second types of microLEDs covered by SiO₂ or SiNₓ or other protective materials. The structure of AlGaInP-based R microLED is entirely different from that of GaN-based microLEDs, generally consisting of n-type GaAs buffer layer, followed by an n-AlAs/AlGaAs distributed Bragg reflector layer, AlGaInP/GaInP multi-quantum wells and barriers, and then p-type AlInP and p-type GaP layers.

What is claimed:

1. A micro light-emitting diode (microLED) comprising:
A buffer layer, or both template and buffer layers.
Each type of microLED, which emits a distinct wavelength, may include additional layers beyond the standard n-type, p-type, and active layers.
Available in varying sizes.

2. The microLED of claim 1, wherein more than one type of microLED can be grown together on a single substrate, horizontally and separately, using SiO₂, SiNₓ or another suitable material as a mask to define the growth area for each type of microLED. This mask can be removed after the growth of each type of microLED.

3. The microLED of claims 1 and 2, wherein all microLEDs are grown using only III-nitride materials (gallium nitride, aluminum nitride, and indium nitride) or in combination with other semiconductor materials, such as AlGaInP or AlGaAs.

4. The microLED of claims 1 and 2, wherein only one type of microLED is grown at a time, and it can be red, green, blue, or another color.

5. The microLED of claims 1 and 2, wherein each type of microLED emits a particular wavelength.

6. The microLED of claims 1 and 2, wherein each type of microLED has the same structure and emits the same emission wavelength or light color.

7. The microLED of claims 1 and 2, wherein all microLEDs can share a template material layer, which may be AlN, h-BN, or other suitable materials.

8. The microLED of claims 1 and 2, wherein all microLEDs can share a buffer layer, which may be GaN, h-BN, or other suitable materials.

9. The microLED of claims 1 and 2, wherein all microLEDs may or may not share the n-type layer(s).

10. The microLED of claims 1 and 2, wherein each type of microLED has its own n-type layer(s), p-type layer(s), active layer(s), and any additional layers as required.

11. The microLED of claims 1 and 2, wherein multiple types of microLEDs may have the same or varying orientations, pitches, and sizes to accommodate different application purposes.

12. The microLED of claims 1 and 2, wherein all microLEDs may vary in sizes and pitches, either locally or across the entire substrate, to achieve different transparencies, depending on the application.

13. The microLED of claims 1 and 2, wherein each microLED may have multiple layers to support the n-type, p-type, and active layers, including superlattice, electron-blocking, and cap layers, among others.

14. The microLED of claims 1 and 2, wherein each type of microLED may have different n-type and p-type doping concentrations, thicknesses, and material qualities for each layer.

15. The microLED of claims 1 and 2, wherein the growth process can be carried out using metal-organic chemical vapor deposition, molecular beam epitaxy, or other material growth systems.

16. The microLED of claims 1 and 2, wherein one or more type of microLEDs may be grown with a specific material layer on the top of the structure to be connected to the transparent or opaque electrical connections and the backplane later.

17. The microLED of claims 1 and 2, wherein one or more types of microLEDs can have a final shape that is different from the shape after growth by applying a dry and/or wet etching technique.

18. The microLED of claims 1 and 2, wherein a microLED can be grown on and share a substrate with another device that is not a microLED.

19. The microLED of claim 18, wherein it can be a transistor or a diode, such as a high-electron mobility transistor, Fin field-effect transistor, Schottky diode, photodiode, solar cell, etc.

20. The micro light-emitting diode of claim 1, wherein one or more types of microLEDs can be grown using individual or combined methods of MOCVD, MBE, or other suitable vacuum systems.
